(19) United States
(12) Patent Application Publication
(10) Pub. No.: US 2020/0227560 A1
(43) Pub. Date: Jul. 16, 2020

(54) SEMICONDUCTOR DEVICE AND DISPLAY DEVICE

(71) Applicant: Sharp Kabushiki Kaisha, Sakai City, Osaka (JP)

(72) Inventors: Toshikatsu ITOH, Sakai City (JP); Hajime IMAI, Sakai City (JP); Hideki KITAGAWA, Sakai City (JP); Tetsuo KIKUCHI, Sakai City (JP); Setsuji NISHIMIYA, Sakai City (JP); Teruyuki UEDA, Sakai City (JP); Kengo HARA, Sakai City (JP); Tohru DAITOH, Sakai City (JP); Masahiko SUZUKI, Sakai City (JP)

(21) Appl. No.: 16/491,248

(22) PCT Filed: Mar. 1, 2018
(86) PCT No.: PCT/JP2018/007695

§ 371 Date: Sep. 5, 2019

(30) Foreign Application Priority Data
Mar. 6, 2017 (JP) 2017-041768

(51) Int. Cl. H01L 29/786; H01L 27/12

(52) U.S. Cl. CPC H01L 29/7869; H01L 29/78696; H01L 27/124; H01L 27/1225

(57) ABSTRACT

A semiconductor device (100) of an embodiment of the present invention includes: a substrate (1); a plurality of TFTs (10) supported by the substrate; and a protecting layer (20) covering the plurality of TFTs. Each of the TFTs is a back channel etch type TFT which includes a gate electrode (2), a gate insulating layer (3), an oxide semiconductor layer (4), a source electrode (5) and a drain electrode (6). The gate electrode includes a tapered portion (TP) defined by a lateral surface (2s) which has a tapered shape. When viewed in a direction normal to a substrate surface, a periphery of the oxide semiconductor layer includes an edge (4e1, 4e2) which extends in a direction intersecting a channel width direction (DW) and which is more internal than an edge of the gate electrode in the channel width direction. The distance from the edge of the oxide semiconductor layer to an inside end of the tapered portion is not less than 1.5 μm.

### TECHNICAL FIELD

The present invention relates to a semiconductor device and particularly to a semiconductor device which includes thin film transistors which include an oxide semiconductor layer as an active layer (oxide semiconductor TFTs). The present invention also relates to a display device which includes such a semiconductor device.

### BACKGROUND ART

An active matrix substrate for use in a liquid crystal display device or the like includes a switching element, such as a thin film transistor (hereinafter, “TFT”), in each pixel. As such a switching element, a TFT which includes an amorphous silicon film as the active layer (hereinafter, “amorphous silicon TFT”) and a TFT which includes a polycrystalline silicon film as the active layer (hereinafter, “polycrystalline silicon TFT”) have been widely used in conventional devices.

In recent years, using an oxide semiconductor as a material of the active layer of TFTs, instead of amorphous silicon and polycrystalline silicon, has been proposed. Such TFTs are referred to as “oxide semiconductor TFTs”. Patent Document No. 1 discloses an active matrix substrate in which an In—Ga—Zn—O based semiconductor film is used for the active layer of a TFT.

The oxide semiconductor has higher mobility than the amorphous silicon. Therefore, oxide semiconductor TFTs are capable of higher speed operation than amorphous silicon TFTs. Further, oxide semiconductor films can be formed through a simpler and more convenient process than polycrystalline silicon films and are therefore applicable to devices which require large surfaces.

The configuration of TFTs can be generally classified into “bottom gate configuration” and “top gate configuration”. Presently, many oxide semiconductor TFTs employ the bottom gate configuration. Known examples of the bottom gate configuration TFTs include etch stop (ES) type TFTs, in which an etch stop layer is provided above the channel region, and back channel etch (BCE) type TFTs, in which an etch stop layer is not provided above the channel region.

### CITATION LIST

### Patent Literature

Patent Document No. 1: Japanese Laid-Open Patent Publication No. 2012-134475

Patent Document No. 2: WO 2012/132953

### SUMMARY OF INVENTION

### Technical Problem

In an oxide semiconductor layer TFT, when a reductive gas (e.g., hydrogen gas) comes into contact with an oxide semiconductor layer during the manufacturing process or the like, oxygen deficiencies occur so that the characteristics of the TFT disadvantageously vary. It is also known that the TFT characteristics vary due to entry of external moisture, or the like, into the oxide semiconductor layer after driving for a long duration or after an aging test. Specifically, when a n-type oxide semiconductor layer undergoes reduction due to entry of moisture, or the like, there is a probability that the threshold voltage Vth will shift to the negative side, so that the off-leak current can increase or depletion (normally-on state) can occur, leading to a display failure.

For example, in a back channel etch type oxide semiconductor TFT, the channel region of the oxide semiconductor layer between the source electrode and the drain electrode is covered with a protecting layer (also, referred to as “passivation layer”). However, when a silicon nitride (SiNx) layer or the like is formed as the protecting layer, hydrogen diffuses into the oxide semiconductor layer in this step so that the characteristics of the TFT disadvantageously vary. Also in the back channel etch type TFT, there are many steps at the ends of respective layers, and the coverage by the protecting layer (step coverage) is not sufficient. Thus, in some cases, this configuration fails to prevent a gas or moisture from reaching the oxide semiconductor layer even after the protecting layer has been formed.

In view of the above, various solutions have been suggested for preventing a gas or moisture from reaching the oxide semiconductor layer. However, there is a probability that the conventional solutions will fail to sufficiently suppress depletion of the oxide semiconductor TFT or cannot achieve desirable device characteristics without complicating the manufacturing process and hence incurring an increase of the manufacturing cost.

For example, Patent Document 2 discloses a configuration where a protecting film is provided so as to cover a flattening resin film provided on an oxide semiconductor TFT. In the configuration of Patent Document 2, a highly-absorbent flattening resin film (organic photosensitive resin or the like) is covered with a dampproof protecting film (SiNx film or the like), whereby entry of moisture into the flattening resin film is suppressed. Patent Document 2 also discloses a configuration where an edge face of the flattening resin film is provided inside or under a sealant, whereby entry of moisture from the outside of a liquid crystal panel into the flattening resin film is suppressed. This prevents moisture from reaching the oxide semiconductor layer via the flattening resin film.

However, in the configuration where the edge face of the flattening resin film is provided inside the sealant, if a peripheral circuit (e.g., gate monolithic circuit) is provided under the sealant, the flattening resin film is not present above TFTs for the peripheral circuit. Thus, there is a probability that the TFTs for the peripheral circuit will be destroyed by a spacer inside the sealant. If the peripheral circuit is not provided under the sealant, i.e., if the peripheral circuit is provided outside the sealant, destruction of the TFTs for the peripheral circuit can be prevented, but in such a case, the frame region increases.

In the configuration where the edge face of the flattening resin film is provided under the sealant, the flattening resin film can be present above the TFTs for the peripheral circuit. However, in that case, if a crack is formed in the dampproof protecting film by the spacer inside the sealant, moisture enters through that crack into the flattening resin film.

The present invention was conceived in view of the above problems. An object of the present invention is to realize stable TFT characteristics in a semiconductor device which includes oxide semiconductor TFTs.

### Solution to Problem

A semiconductor device of an embodiment of the present invention includes: a substrate; a plurality of thin film transistors supported by the substrate; and a protecting layer covering the plurality of thin film transistors, wherein each of the plurality of thin film transistors is a back channel etch type thin film transistor, the back channel etch type thin film transistor including a gate electrode provided on the substrate, a gate insulating layer covering the gate electrode, an oxide semiconductor layer which is provided on the gate insulating layer and which opposes the gate electrode with the gate insulating layer interposed therebetween, and a source electrode and a drain electrode which are electrically coupled with the oxide semiconductor layer, the gate electrode includes a tapered portion defined by a lateral surface which has a tapered shape, and when viewed in a direction normal to a substrate surface, a periphery of the oxide semiconductor layer includes an edge which extends in a direction intersecting a channel width direction and which is more internal than an edge of the gate electrode in the channel width direction, a distance from the edge of the oxide semiconductor layer to an inside end of the tapered portion is not less than 1.5 μm.

In one embodiment, the protecting layer is an inorganic insulating layer which is made of an inorganic insulative material.

In one embodiment, the protecting layer includes a silicon oxide layer which is in contact with the oxide semiconductor layer and a silicon nitride or silicon nitride oxide layer provided on the silicon oxide layer.

In one embodiment, the semiconductor device of the present invention is an active matrix substrate which has a display region defined by a plurality of pixels and a peripheral region located around the display region.

In one embodiment, the semiconductor device of the present invention includes a pixel thin film transistor provided in each of the plurality of pixels, and the plurality of thin film transistors include the pixel thin film transistor.

In one embodiment, the semiconductor device of the present invention includes a peripheral circuit which is provided in the peripheral region and which includes at least one circuit thin film transistor, and the plurality of thin film transistors include the at least one circuit thin film transistor.

In one embodiment, the oxide semiconductor layer includes an In—Ga—Zn—O based semiconductor.

In one embodiment, the In—Ga—Zn—O based semiconductor includes a crystalline portion.

In one embodiment, the oxide semiconductor layer has a multilayer structure.

A display device of an embodiment of the present invention includes: an active matrix substrate; a counter substrate located opposite to the active matrix substrate; and a display medium layer provided between the active matrix substrate and the counter substrate, wherein the active matrix substrate is the semiconductor device as set forth in any of the foregoing paragraphs.

### Advantageous Effects of Invention

According to an embodiment of the present invention, in a semiconductor device which includes oxide semiconductor TFTs, stable TFT characteristics can be realized.

### BRIEF DESCRIPTION OF DRAWINGS

FIG. 1 is a plan view schematically showing a semiconductor device (TFT substrate) 100 of an embodiment of the present invention. FIG. 1 shows the entirety of the semiconductor device 100.

FIG. 2 is a plan view schematically showing the semiconductor device 100. FIG. 2 shows a region corresponding to a single pixel P of the semiconductor device 100.

FIG. 3 is a cross-sectional view schematically showing the semiconductor device 100. FIG. 3 shows a cross section taken along line 3A-3A′ of FIG. 2.

FIG. 4 is a cross-sectional view schematically showing the semiconductor device 100. FIG. 4 shows a cross section taken along line 4A-4A′ of FIG. 2.

FIG. 5 is a cross-sectional view schematically showing the semiconductor device 100. FIG. 5 shows a cross-sectional configuration of a TFT 10 in a cross section parallel to the channel width direction DW.

FIG. 6 is a diagram showing a planar configuration of the TFT 10.

FIG. 7 is a cross-sectional view showing a semiconductor device 900 of a comparative example.

FIG. 8 is a cross-sectional view schematically showing the semiconductor device 100. FIG. 8 shows the vicinity of an edge 4e1 of an oxide semiconductor layer 4 of the TFT 10.

FIG. 9 is a cross-sectional view showing the semiconductor device 900 of the comparative example.

FIG. 10(a), FIG. 10(b) and FIG. 10(c) are stepwise cross-sectional views illustrating manufacturing steps of the semiconductor device 100.

FIG. 11(a) and FIG. 11(b) are stepwise cross-sectional views illustrating manufacturing steps of the semiconductor device 100.

FIG. 12(a) and FIG. 12(b) are stepwise cross-sectional views illustrating manufacturing steps of the semiconductor device 100.

FIG. 13(a) and FIG. 13(b) are stepwise cross-sectional views illustrating manufacturing steps of the semiconductor device 100.

FIG. 14 is a plan view schematically showing a circuit TFT 10′ included in the semiconductor device 100.

FIG. 15 is a diagram showing a cross section of the semiconductor device 100, which includes the circuit TFT 10′. FIG. 15 shows a cross section taken along line 15A-15A′.

FIG. 16 is a schematic plan view showing an example of the planar configuration of an active matrix substrate 700 of an embodiment of the present invention.

FIG. 17 is a cross-sectional view of a crystalline silicon TFT 710A and an oxide semiconductor TFT 710B in the active matrix substrate 700.

### DESCRIPTION OF EMBODIMENTS

Hereinafter, embodiments of the present invention will be described with reference to the drawings. In the following sections, an active matrix substrate (TFT substrate) for liquid crystal display devices is illustrated as a semiconductor device of an embodiment of the present invention. However, the semiconductor device of an embodiment of the present invention may be an active matrix substrate for use in other types of display devices, for example, electrophoretic display devices, MEMS (Micro Electro Mechanical System) display devices, organic EL (Electroluminescence) display devices, etc.

### Embodiment 1

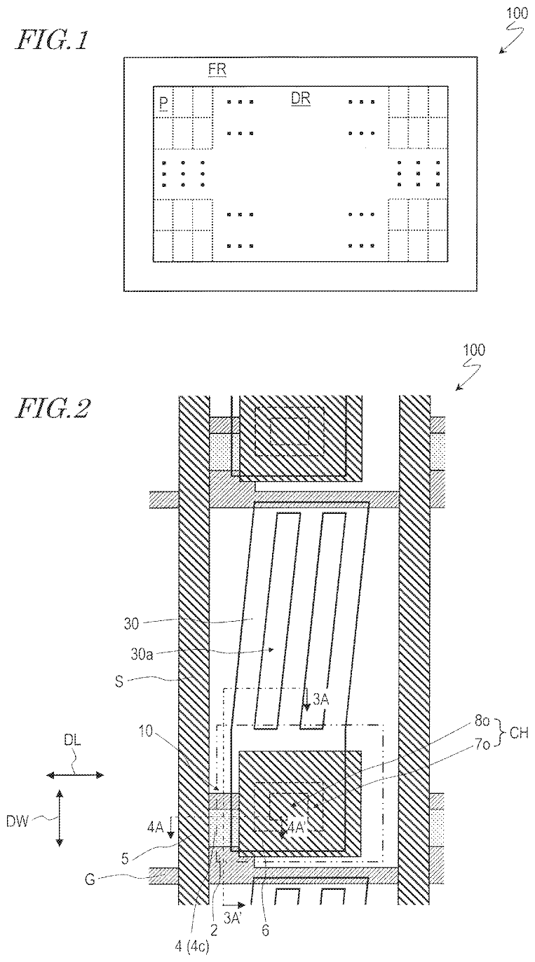

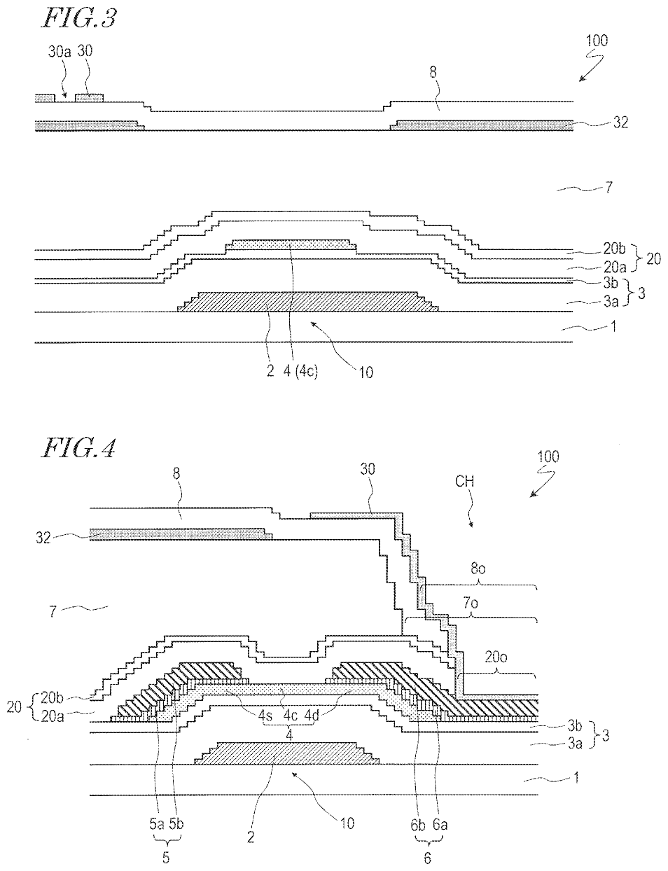

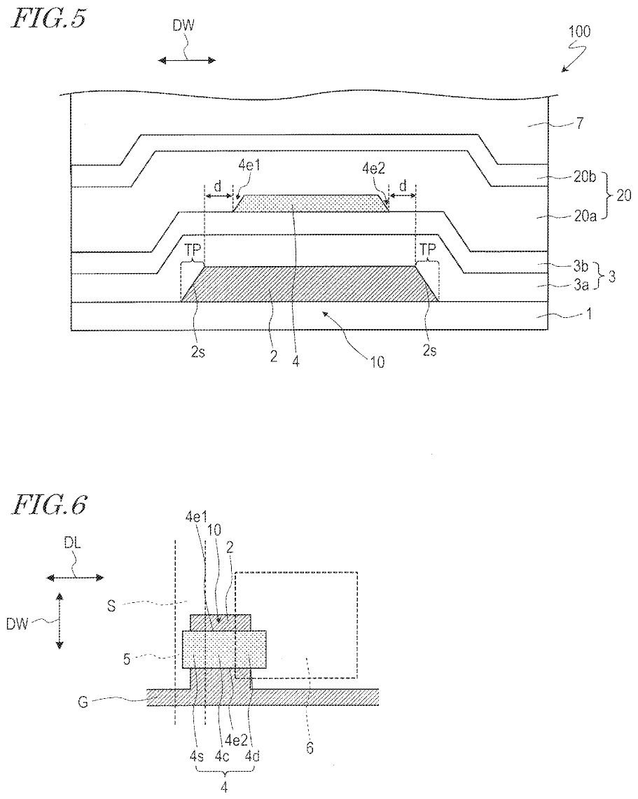

A semiconductor device (TFT substrate) 100 of the present embodiment is described with reference to FIG. 1 to FIG. 4. FIG. 1 and FIG. 2 are plan views schematically showing the semiconductor device 100. FIG. 1 shows the entirety of the semiconductor device 100. FIG. 2 shows a region corresponding to a single pixel P of the semiconductor device 100. FIG. 3 and FIG. 4 are cross-sectional views schematically showing the semiconductor device 100. FIG. 3 and FIG. 4 show cross sections respectively taken along line 3A-3A′ and line 4A-4A′ of FIG. 2.

The semiconductor device 100 has, as shown in FIG. 1, a display region DR defined by a plurality of pixels P and a peripheral region (also referred to as “frame region”) FR located around the display region DR. The plurality of pixels P are arranged in a matrix including a plurality of rows and a plurality of columns.

The semiconductor device 100 includes, as shown in FIG. 2, FIG. 3 and FIG. 4, a substrate 1, a plurality of thin film transistors (TFT) 10 supported by the substrate 1, and a protecting layer 20 covering the plurality of TFTs 10. The semiconductor device 100 further includes a plurality of scan lines (gate bus lines) G extending in the row direction, a plurality of signal lines (source bus lines) S extending in the column direction, and pixel electrodes 30 provided in respective ones of the plurality of pixels P.

The substrate 1 is made of an insulative, transparent material. The substrate 1 is, for example, a glass substrate.

Each of the plurality of TFTs 10 is a back channel etch type oxide semiconductor TFT and includes a gate electrode 2, a gate insulating layer 3, an oxide semiconductor layer 4, a source electrode 5 and a drain electrode 6. The TFT 10 shown in FIG. 2 and other drawings is a pixel TFT provided in each pixel P.

The gate electrode 2 is provided on the substrate 1. The gate electrode 2 is electrically coupled with the scan line G and is supplied with a scan signal (gate signal) from the scan line G. In the illustrated example, the gate electrode 2 is extended in the column direction from the scan line G.

The gate insulating layer 3 is arranged so as to cover the gate electrode 2. In the illustrated example, the gate insulating layer 3 includes a silicon nitride (SiNx) layer 3a and a silicon oxide (SiO₂) layer 3b provided on the silicon nitride layer 3a. That is, the gate insulating layer 3 has a multilayer structure.

The oxide semiconductor layer 4 is provided on the gate insulating layer 3. The oxide semiconductor layer 4 is in the form of an island and opposes the gate electrode 2 with the gate insulating layer 3 interposed therebetween.

The source electrode 5 and the drain electrode 6 are electrically coupled with the oxide semiconductor layer 4. In the illustrated example, the source electrode 5 and the drain electrode 6 are each in contact with part of the upper surface of the oxide semiconductor layer 4 (top contact configuration). The source electrode 5 is electrically coupled with the signal line S and is supplied with a display signal (source signal) from the signal line S. In the illustrated example, part of the signal line S (part which is in contact with the oxide semiconductor layer 4) functions as the source electrode 5. The drain electrode 6 is electrically coupled with the pixel electrode 30. In the illustrated example, the source electrode 5 and the drain electrode 6 have a multilayer structure including a lower layer 5a, 6a and an upper layer 5b, 6b which are made of different electrically-conductive materials.

A region 4s of the oxide semiconductor layer 4 which is in contact with the source electrode 5 is referred to as “source region”. A region 4d of the oxide semiconductor layer 4 which is in contact with the drain electrode 6 is referred to as “drain region”. A region 4c of the oxide semiconductor layer 4 which overlaps the gate electrode 2 and which is present between the source region 4s and the drain region 4d is referred to as “channel region”.

In the specification of the present application, in a plane parallel to the substrate surface, a direction DL parallel to the direction of the electric current flowing through the channel region 4c is referred to as “channel length direction”, and a direction DW perpendicular to the channel length direction DL is referred to as “channel width direction”. In the present embodiment, the channel width direction DW is parallel to the column direction (i.e., the channel length direction DL is parallel to the row direction), and the source region 4s, the channel region 4c and the drain region 4d are aligned along the row direction.

The protecting layer (passivation layer) 20 is an inorganic insulating layer which is made of an inorganic insulative material. The protecting layer 20 has a multilayer structure. Specifically, the protecting layer 20 includes a silicon oxide (SiO₂) layer 20a which is in contact with the oxide semiconductor layer 4 and a silicon nitride (SiNx) layer 20b which is provided on the silicon oxide layer 20a. Note that a silicon nitride oxide (SiON) layer may be provided instead of the silicon nitride layer 20b.

On the protecting layer 20, an organic insulating layer 7 is provided. The organic insulating layer 7 is made of, for example, a photosensitive resin material. The organic insulating layer 7 is also referred to as “flattening resin layer”.

On the organic insulating layer 7, a common electrode 32 is provided. The common electrode 32 is made of a transparent, electrically-conductive material. The common electrode 32 is a single electrically-conductive film formed continuously over the plurality of pixels P, thereby giving a common potential across the entire display region DR.

A dielectric layer 8 is provided so as to cover the common electrode 32. The dielectric layer 8 is made of an inorganic insulative material (for example, silicon nitride).

The pixel electrode 30 is provided on the dielectric layer 8. The pixel electrode 30 has at least one slit 30a (in the illustrated example, two slits 30a). The pixel electrode 30 is connected with the drain electrode 6 of the TFT 10 in a contact hole CH. The contact hole CH includes an opening 20o formed in the protecting layer 20, an opening 7o formed in the organic insulating layer 7, and an opening 8o formed in the dielectric layer 8. Note that the common electrode 32 is not provided around the contact hole CH (in a region enclosed with a two-dot chain line in FIG. 2).

The positional relationship between the gate electrode 2 and the oxide semiconductor layer 4 in the semiconductor device 100 of the present embodiment is described more specifically with reference to FIG. 5 and FIG. 6. FIG. 5 is a cross-sectional view of the semiconductor device 100. FIG. 5 shows the cross-sectional configuration of the TFT 10 in a cross section parallel to the channel width direction DW. FIG. 6 is a diagram showing the planar configuration of the TFT 10.

As shown in FIG. 5, the gate electrode 2 includes a tapered portion TP defined by a lateral surface 2s which has a tapered shape. The taper angle of the lateral surface 2s (the angle of the lateral surface 2s with respect to the substrate surface) is less than 90° (for example, about 60°). The shape of the lateral surface 2s is a so-called forwardly-tapered shape.

As shown in FIG. 6, when viewed in a direction normal to the substrate surface, the periphery of the oxide semiconductor layer 4 includes edges 4e1 and 4e2 extending in directions intersecting (herein, generally perpendicular to) the channel width direction DW. These edges 4e1 and 4e2 are more internal than the edge of the gate electrode 2 in the channel width direction DW.

The distance d from the edge 4e1 of the oxide semiconductor layer 4 to the inside end of the tapered portion TP (see FIG. 5) is not less than 1.5 μm. Likewise, the distance d from the edge 4e2 of the oxide semiconductor layer 4 to the inside end of the tapered portion TP is not less than 1.5 μm.

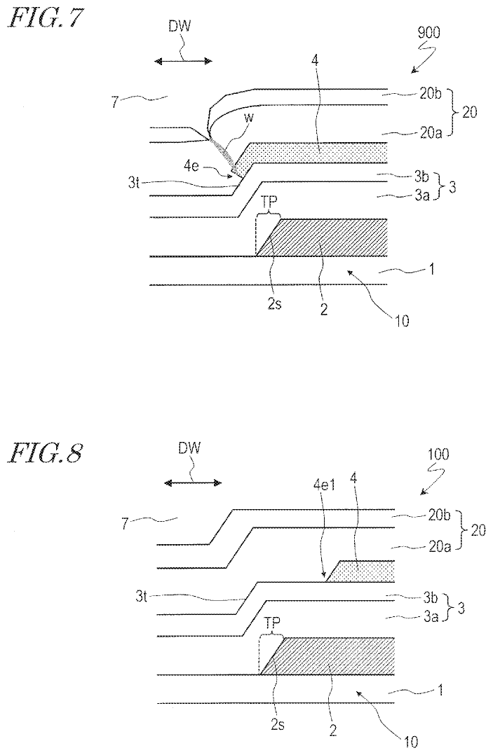

The semiconductor device 100 of the present embodiment has the above-described configuration and therefore can realize stable TFT characteristics. The reasons for this are described with further reference to FIG. 7. FIG. 7 is a cross-sectional view showing a semiconductor device 900 of a comparative example.

The semiconductor device 900 of the comparative example is different from the liquid crystal display device 100 of the present embodiment in the positional relationship between the gate electrode 2 and the oxide semiconductor layer 4 of the TFT 10. In the liquid crystal display device 900 of the comparative example, the edge 4e of the oxide semiconductor layer 4 extending in a direction generally perpendicular to the channel width direction DW is located more external than the edge of the gate electrode 2 in the channel width direction DW. In this case, the edge 4e of the oxide semiconductor layer 4 is present on a tapered surface 3t of the gate insulating layer 3 (which is formed so as to correspond to the tapered portion TP of the gate electrode 2), so that the lateral surface of the oxide semiconductor layer 4 can be inversely tapered with respect to the substrate surface (or be in a state similar to the inversely-tapered state). Therefore, the coverage of the silicon oxide layer 20a that is underlying the protecting layer 20 deteriorates, and voids can occur in the silicon oxide layer 20a. The voids in the silicon oxide layer 20a are not filled even when the silicon nitride layer 20b that is overlying the protecting layer 20 is formed. As shown in FIG. 7, external moisture w enters the oxide semiconductor layer 4 via the organic insulating layer 7 so that the TFT 10 can lead depletion. A hydrogen gas produced in formation of the silicon nitride layer 20b reaches the oxide semiconductor layer 4 via the voids of the silicon oxide layer 20a and deoxidize the oxide semiconductor, and accordingly, depletion of the TFT 10 disadvantageously occurs.

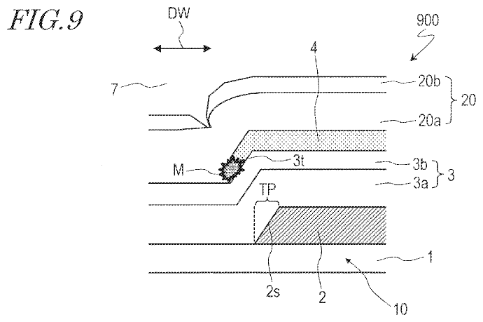

On the other hand, in the semiconductor device 100 of the present embodiment, the edges 4e1 and 4e2 of the oxide semiconductor layer 4 extending in a direction intersecting the channel width direction DW are more internal than the edge of the gate electrode 2 in the channel width direction DW. Therefore, as shown in FIG. 8, the edge 4e1 of the oxide semiconductor layer 4 is not present on the tapered surface 3t of the gate insulating layer 3 (the same applies to the edge 4e2). Thus, the lateral surface of the oxide semiconductor layer 4 is prevented from being inversely tapered. Accordingly, the coverage of the silicon oxide layer 20a that is underlying the protecting layer 20 improves, and occurrence of voids in the silicon oxide layer 20a is suppressed. Hence, depletion attributed to moisture or hydrogen gas from the external environment can be suppressed. Even if the thickness of the silicon nitride layer 20b that is overlying the protecting layer 20 is relatively small, entry of moisture can be sufficiently prevented. Therefore, the thickness of the silicon nitride layer 20b can be reduced. Thus, the amount of the hydrogen gas (eliminated hydrogen) produced in formation of the silicon nitride layer 20b can be reduced, and accordingly, depletion of the TFT 10 can be further suppressed. As previously described, according to the semiconductor device 100 of the present embodiment, stable TFT characteristics can be realized.

In the semiconductor device 900 of the comparative example, the lateral surface of the oxide semiconductor layer (the lateral surface which is present on the tapered surface 3t of the gate insulating layer 3) is inversely tapered, i.e., forms an overhang with respect to the normal of the substrate surface (or falling in a state similar to the overhang). Therefore, in forming the source electrode 5 and the drain electrode 6, as shown in FIG. 9, the metal material M is likely to remain in the vicinity of the lateral surface of the oxide semiconductor layer 4. For example, when a Ti layer is used as the underlayer of the source electrode 5 and the drain electrode 6, Ti is likely to remain at the lateral surface of the oxide semiconductor layer 4 in patterning the Ti film by dry etching. The remaining metal material M can cause current leakage. On the other hand, in the semiconductor device 100 of the present embodiment, occurrence of current leakage which is attributed to the metal material M remaining in the vicinity of the lateral surface of the oxide semiconductor layer 4 can also be prevented.

The position of the oxide semiconductor layer 4 relative to the gate electrode 2 can sometimes deviate from a desired position (designed position) due to the factors in the manufacturing process. Therefore, from the viewpoint of more surely realizing stable TFT characteristics, it is preferred that the distance d from the edges 4e1 and 4e2 of the oxide semiconductor layer 4 to the inside end of the tapered portion TP is not less than a predetermined value. The present inventors carried out detailed research and found that the distance d is preferably not less than 1.5 μm, more preferably not less than 2.0 μm, in consideration of the line width variation, the photoalignment accuracy, and other factors in the gate electrode 2 and the oxide semiconductor layer 4. When the distance d is not less than 1.5 μm, the edges 4e1 and 4e2 of the oxide semiconductor layer 4 are more surely prevented from being present on the tapered surface 3t of the gate insulating layer 3.

[Manufacturing Method]

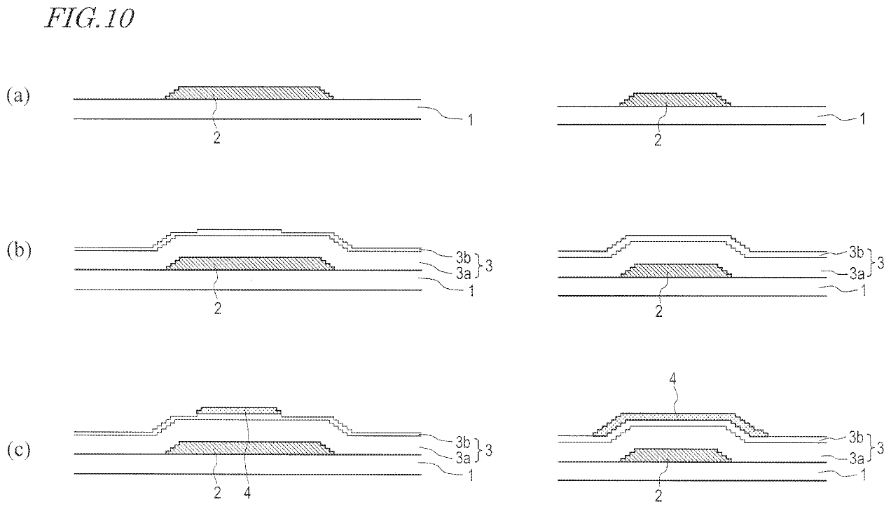

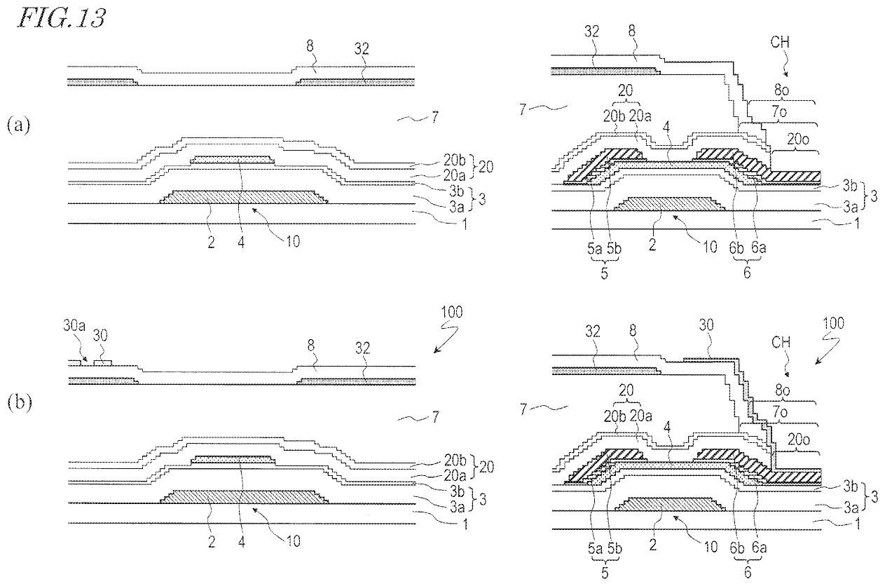

An example of the manufacturing method of the semiconductor device 100 is described with reference to FIG. to FIG. 13. FIG. 10 to FIG. 13 are stepwise cross-sectional views illustrating the manufacturing steps of the semiconductor device 100. In the drawings, the left part shows a cross section corresponding to FIG. 3, and the right part shows a cross section corresponding to FIG. 4.

First, as shown in FIG. 10(a), an electrically-conductive film is deposited on a substrate (for example, glass substrate) 1, and this resultant electrically-conductive film is patterned using a photolithography process (application of a photo resist, exposure, development, etching, removal of the resist), whereby a gate electrode 2 and a scan line G (not shown herein) are formed. The etching is, for example, wet etching. The gate electrode 2 and the scan line G have a multilayer structure in which, for example, a Ti layer of not less than 5 nm and not more than 100 nm in thickness and a Cu layer of not less than 100 nm and not more than 500 nm in thickness are stacked up in this order.

Then, as shown in FIG. 10(b), a gate insulating layer 3 is formed so as to cover the gate electrode 2 and the scan line G. The gate insulating layer 3 has a multilayer structure in which, for example, a silicon nitride (SiNx) layer 3a of not less than 50 nm and not more than 500 nm in thickness and a silicon oxide (SiO₂) layer 3b of not less than 25 nm and not more than 500 nm in thickness are stacked up in this order.

Then, as shown in FIG. 10(c), an oxide semiconductor film is deposited on the gate insulating layer 3, and this oxide semiconductor film is annealed at a predetermined temperature and thereafter patterned using a photolithography process, whereby an oxide semiconductor layer 4 is formed. The oxide semiconductor layer 4 is an In—Ga—Zn—O based semiconductor layer of, for example, not less than 5 nm and not more than 200 nm in thickness.

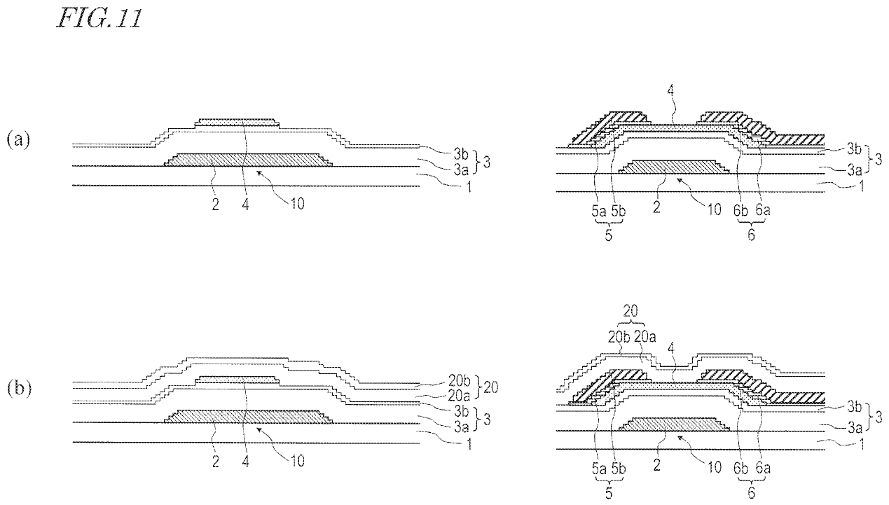

Then, as shown in FIG. 11(a), an electrically-conductive film is deposited, and this electrically-conductive film is patterned using a photolithography process, whereby a source electrode 5, a drain electrode 6 and a signal line S are formed. The lower layer 5a, 6a of the source electrode 5, the drain electrode 6 and the signal line S is a Ti layer of, for example, not less than 5 nm and not more than 100 nm in thickness, and the upper layer 5b, 6b is a Cu layer of, for example, not less than 100 nm and not more than 500 nm in thickness. The etching on the upper layer 5b, 6b is realized by, for example, wet etching. The etching on the lower layer 5a, 6a is realized by, for example, dry etching.

Then, as shown in FIG. 11(b), a protecting layer 20 is formed so as to cover the oxide semiconductor layer 4, the source electrode 5, the drain electrode 6, and other elements. The thickness of the silicon oxide layer 20a of the protecting layer 20 is, for example, not less than 200 nm and not more than 500 nm, and the thickness of the silicon nitride layer 20b is, for example, more than 0 nm and not more than 100 nm. Note that the silicon nitride layer 20b may be replaced by a silicon nitride oxide layer.

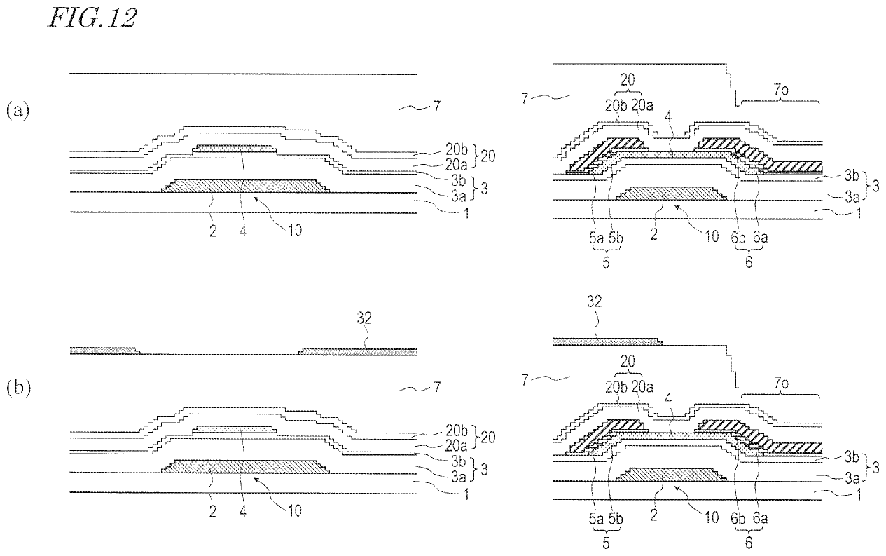

Then, as shown in FIG. 12(a), an organic insulating layer 7 is formed on the protecting layer 20. The organic insulating layer 7 is made of, for example, a photosensitive resin material. The thickness of the organic insulating layer 7 is, for example, not less than 1 μm and not more than 3 μm. The organic insulating layer 7 has an opening 7o at the position corresponding to the contact hole CH.

Then, as shown in FIG. 12(b), a transparent electrically-conductive film is deposited on the organic insulating layer 7, and this transparent electrically-conductive film is patterned using a photolithography process, whereby a common electrode 32 is formed. The common electrode 32 is, for example, an ITO layer of not less than 50 nm and not more than 200 nm in thickness.

Then, as shown in FIG. 13(a), a dielectric layer 8 is formed so as to cover the common electrode 32. The dielectric layer 8 is a SiNx layer of, for example, not less than 100 nm and not more than 400 nm in thickness. The dielectric layer 8 and the protecting layer 20 have openings 8o, 20o formed through a photolithography process at the position corresponding to the contact hole CH.

Thereafter, as shown in FIG. 13(b), a transparent electrically-conductive film is deposited on the dielectric layer 8, and this transparent electrically-conductive film is patterned using a photolithography process, whereby a pixel electrode 30 with a slit 30a is formed. The pixel electrode 30 is, for example, an ITO layer of not less than 50 nm and not more than 200 nm in thickness. In this way, the semiconductor device 100 can be manufactured.

[Circuit TFT]

The semiconductor device 100 may include a peripheral circuit which is provided in the peripheral region FR and which includes at least one circuit TFT. The peripheral circuit is, for example, a gate driver (scan line driving circuit) monolithically formed on the substrate 1.

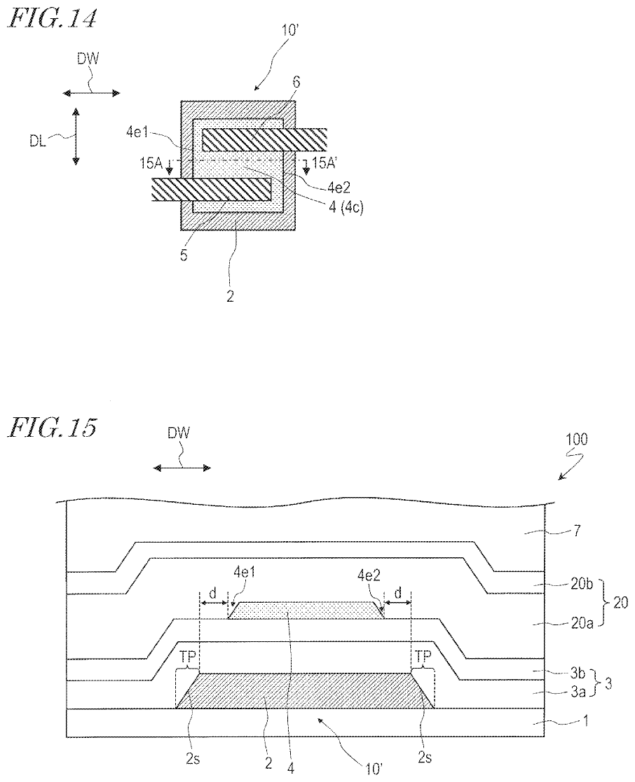

FIG. 14 and FIG. 15 show an example of the circuit TFT 10′. FIG. 14 is a plan view schematically showing the circuit TFT 10′. FIG. 15 is a diagram showing a cross section of the semiconductor device 100, which includes the circuit TFT 10′. FIG. 15 shows a cross section taken along line 15A-15A′.

The circuit TFT 10′ includes a gate electrode 2, a gate insulating layer 3, an oxide semiconductor layer 4, a source electrode 5 and a drain electrode 6 as does the pixel TFT 10. That is, the circuit TFT 10′ is also an oxide semiconductor TFT.

As shown in FIG. 15, the gate electrode 2 of the circuit TFT 10′ also includes a tapered portion TP defined by a lateral surface 2s which has a tapered shape. As shown in FIG. 14, when viewed in a direction normal to the substrate surface, the periphery of the oxide semiconductor layer 4 includes edges 4e1 and 4e2 extending in directions intersecting (herein, generally perpendicular to) the channel width direction DW. These edges 4e1 and 4e2 are more internal than the edge of the gate electrode 2 in the channel width direction DW.

The distance d from the edge 4e1 of the oxide semiconductor layer 4 to the inside end of the tapered portion TP is not less than 1.5 μm. Likewise, the distance d from the edge 4e2 of the oxide semiconductor layer 4 to the inside end of the tapered portion TP is not less than 1.5 μm.

Due to the circumstance that the circuit TFT 10′ has the above-described configuration, the same effects as those previously described about the pixel TFT 10 can be achieved. That is, for the circuit TFT 10′, stable TFT characteristics can be realized.

[Regarding Oxide Semiconductor]

The oxide semiconductor included in the oxide semiconductor layer 4 may be an amorphous oxide semiconductor or may be a crystalline oxide semiconductor which includes a crystalline portion. Examples of the crystalline oxide semiconductor include a polycrystalline oxide semiconductor, a microcrystalline oxide semiconductor, and a crystalline oxide semiconductor in which the c-axis is oriented generally perpendicular to the layer surface.

The oxide semiconductor layer 4 may have a multilayer structure consisting of two or more layers. When the oxide semiconductor layer 4 has a multilayer structure, the oxide semiconductor layer 4 may include an amorphous oxide semiconductor layer and a crystalline oxide semiconductor layer, may include a plurality of crystalline oxide semiconductor layers which have different crystalline structures, or may include a plurality of amorphous oxide semiconductor layers. When the oxide semiconductor layer 4 has a two-layer structure which includes the upper layer and the lower layer, it is preferred that the energy gap of the oxide semiconductor included in the upper layer is greater than the energy gap of the oxide semiconductor included in the lower layer. Note that, however, when the difference in energy gap between these layers is relatively small, the energy gap of the oxide semiconductor of the lower layer may be greater than the energy gap of the oxide semiconductor of the upper layer.

The materials, structures and film formation methods of the amorphous oxide semiconductor and the respective aforementioned crystalline oxide semiconductors, and the configuration of the oxide semiconductor layer which has a multilayer structure, are disclosed in, for example, Japanese Laid-Open Patent Publication No. 2014-007399. The entire disclosure of Japanese Laid-Open Patent Publication No. 2014-007399 is incorporated by reference in this specification.

The oxide semiconductor layer 4 may include, for example, at least one metal element among In, Ga and Zn. In the present embodiment of the present invention, the oxide semiconductor layer 15 includes, for example, an In—Ga—Zn—O based semiconductor (e.g., indium gallium zinc oxide). Here, the In—Ga—Zn—O based semiconductor is a ternary oxide including In (indium), Ga (gallium) and Zn (zinc). The proportion (composition ratio) of In, Ga and Zn is not particularly limited but includes, for example, In:Ga:Zn=2:2:1, In:Ga:Zn=1:1:1, and In:Ga:Zn=1:1:2. The oxide semiconductor layer 4 which has such a composition can be formed by an oxide semiconductor film which includes an In—Ga—Zn—O based semiconductor.

The In—Ga—Zn—O based semiconductor may be amorphous or may be crystalline. As the crystalline In—Ga—Zn—O based semiconductor, a crystalline In—Ga—Zn—O based semiconductor in which the c-axis is oriented generally perpendicular to the layer surface is preferred.

The crystalline structure of the crystalline In—Ga—Zn—O based semiconductor is disclosed in, for example, aforementioned Japanese Laid-Open Patent Publication No. 2014-007399, Japanese Laid-Open Patent Publication No. 2012-134475, and Japanese Laid-Open Patent Publication No. 2014-209727. The entire disclosures of Japanese Laid-Open Patent Publication No. 2012-134475 and Japanese Laid-Open Patent Publication No. 2014-209727 are incorporated by reference in this specification. A TFT which includes an In—Ga—Zn—O based semiconductor layer has high mobility (20 times or more as compared with an a-Si TFT) and low current leakage (less than 1/100 as compared with an a-Si TFT), and is therefore suitably used as a driver TFT (e.g., a TFT included in a driving circuit provided around the display region including a plurality of pixels on the same substrate as the display region) and a pixel TFT (a TFT provided in a pixel).

The oxide semiconductor layer 4 may contain a different oxide semiconductor instead of the In—Ga—Zn—O based semiconductor. For example, the oxide semiconductor layer 4 may contain an In—Sn—Zn—O based semiconductor (e.g., In₂O₃—SnO₂—ZnO; InSnZnO). In—Sn—Zn—O based semiconductor is a ternary oxide including In (indium), Sn (tin) and Zn (zinc). Alternatively, the oxide semiconductor layer 4 may contain an In—Al—Zn—O based semiconductor, an In—Al—Sn—Zn—O based semiconductor, a Zn—O based semiconductor, an In—Zn—O based semiconductor, a Zn—Ti—O based semiconductor, a Cd—Ge—O based semiconductor, a Cd—Pb—O based semiconductor, a CdO (cadmium oxide), a Mg—Zn—O based semiconductor, an In—Ga—Sn—O based semiconductor, an In—Ga—O based semiconductor, a Zr—In—Zn—O based semiconductor, a Hf—In—Zn—O based semiconductor, or the like.

### Embodiment 2

Hereinafter, another embodiment of the semiconductor device of the present invention is described with reference to the drawings. The semiconductor device of the present embodiment is an active matrix substrate which includes oxide semiconductor TFTs and crystalline silicon TFTs on the same substrate.

The active matrix substrate includes a TFT (pixel TFT) in each pixel. As the pixel TFT, an oxide semiconductor TFT which includes, for example, an In—Ga—Zn—O based semiconductor film as the active layer is used.

Part or the entirety of the peripheral driving circuit may be integrally formed on the same substrate as the pixel TFTs. Such an active matrix substrate is referred to as a driver-monolithic active matrix substrate. In the driver-monolithic active matrix substrate, the peripheral driving circuit is provided in a region (non-display region or frame region) exclusive of a region including a plurality of pixels (display region). TFTs which are constituents of the peripheral driving circuit (circuit TFTs) are, for example, crystalline silicon TFTs which include a polycrystalline silicon film as the active layer. Thus, when oxide semiconductor TFTs are used as the pixel TFTs and crystalline silicon TFTs are used as the circuit TFTs, the power consumption can be reduced in the display region, and further, the frame region can be reduced.

The TFT 10 which has been described with reference to FIG. 2 to FIG. 6 is applicable to the pixel TFTs. This point will be described later.

Next, a more specific configuration of the active matrix substrate of the present embodiment is described with reference to the drawings.

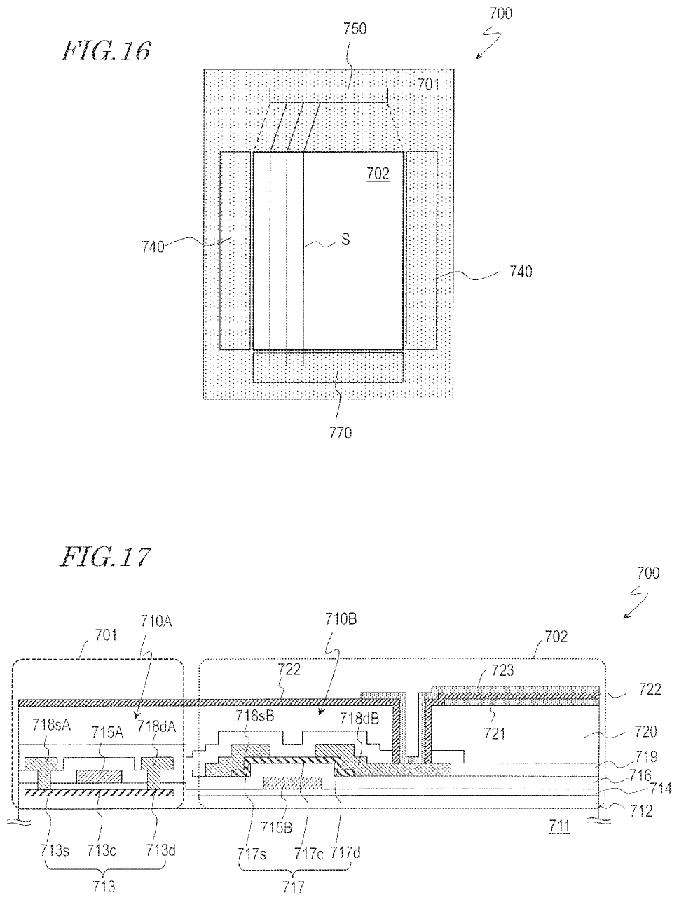

FIG. 16 is a schematic plan view showing an example of a planar configuration of an active matrix substrate 700 of the present embodiment. FIG. 17 is a cross-sectional view showing a cross-sectional configuration of a crystalline silicon TFT (hereinafter, referred to as “first thin film transistor”) 710A and an oxide semiconductor TFT (hereinafter, referred to as “second thin film transistor”) 710B in the active matrix substrate 700.

As shown in FIG. 16, the active matrix substrate 700 includes a display region 702 including a plurality of pixels and a region exclusive of the display region 702 (non-display region). The non-display region includes a driving circuit formation region 701 in which the driving circuit is to be provided. In the driving circuit formation region 701, for example, a gate driver circuit 740 and a check circuit 770 are provided. In the display region 702, a plurality of gate bus lines (not shown) extending in the row direction and a plurality of source bus lines S extending in the column direction are provided. Although not shown, each pixel is defined by the gate bus lines and the source bus lines S. The gate bus lines are respectively connected with corresponding terminals of the gate driver circuit. The source bus lines S are respectively connected with corresponding terminals of a driver IC 750 mounted to the active matrix substrate 700.

As shown in FIG. 17, in the active matrix substrate 700, the second thin film transistor 710B is provided as a pixel TFT in each pixel of the display region 702, and the first thin film transistor 710A is provided as a circuit TFT in the driving circuit formation region 701.

The active matrix substrate 700 includes a substrate 711, an underlayer film 712 provided on the surface of the substrate 711, a first thin film transistor 710A provided on the underlayer film 712, and a second thin film transistor 710B provided on the underlayer film 712. The first thin film transistor 710A is a crystalline silicon TFT in which the active region mainly contains crystalline silicon. The second thin film transistor 710B is an oxide semiconductor TFT in which the active region mainly contains an oxide semiconductor. The first thin film transistor 710A and the second thin film transistor 710B are integrally formed in the substrate 711. The “active region” mentioned herein refers to part of a semiconductor layer that is to be the active layer of the TFT in which a channel is to be formed.

The first thin film transistor 710A includes a crystalline silicon semiconductor layer (e.g., low-temperature polysilicon layer) 713 provided on the underlayer film 712, a first insulating layer 714 covering the crystalline silicon semiconductor layer 713, and a gate electrode 715A provided on the first insulating layer 714. Part of the first insulating layer 714 which is present between the crystalline silicon semiconductor layer 713 and the gate electrode 715A functions as the gate insulating film of the first thin film transistor 710A. The crystalline silicon semiconductor layer 713 includes a region 713c in which a channel is to be formed (active region) and a source region 713s and a drain region 713d which are located at opposite sides of the active region. In this example, part of the crystalline silicon semiconductor layer 713 overlapping the gate electrode 715A with the first insulating layer 714 interposed therebetween forms an active region 713c. The first thin film transistor 710A also includes a source electrode 718sA and a drain electrode 718dA which are connected with the source region 713s and the drain region 713d, respectively. The source and drain electrodes 718sA, 718dA may be provided on an interlayer insulating film (herein, a second insulating layer 716) that covers the gate electrode 715A and the crystalline silicon semiconductor layer 713 so as to be connected with the crystalline silicon semiconductor layer 713 inside a contact hole formed in the interlayer insulating film.

The second thin film transistor 710B includes a gate electrode 715B provided on the underlayer film 712, a second insulating layer 716 covering the gate electrode 715B, and an oxide semiconductor layer 717 provided on the second insulating layer 716. As illustrated, the first insulating layer 714 which is the gate insulating film of the first thin film transistor 710A may be extended to a region in which the second thin film transistor 710B is to be formed. In this case, the oxide semiconductor layer 717 may be provided on the first insulating layer 714. Part of the second insulating layer 716 which is present between the gate electrode 715B and the oxide semiconductor layer 717 functions as the gate insulating film of the second thin film transistor 710B. The oxide semiconductor layer 717 includes a region 717c in which a channel is to be formed (active region) and a source contact region 717s and a drain contact region 717d which are located at opposite sides of the active region. In this example, part of the oxide semiconductor layer 717 overlapping the gate electrode 715B with the second insulating layer 716 interposed therebetween forms an active region 717c. The second thin film transistor 710B further includes a source electrode 718sB and a drain electrode 718dB which are connected with the source contact region 717s and the drain contact region 717d, respectively. Note that the second thin film transistor 710B can alternatively be configured such that the underlayer film 712 is not provided on the substrate 711.

The thin film transistors 710A, 710B are covered with a passivation film 719 and a flattening film 720. In the second thin film transistor 710B which functions as a pixel TFT, the gate electrode 715B is connected with a gate bus lines (not shown), the source electrode 718sB is connected with a source bus line (not shown), and the drain electrode 718dB is connected with a pixel electrode 723. In this example, the drain electrode 718dB is connected with a corresponding pixel electrode 723 inside an opening formed in the passivation film 719 and the flattening film 720. A video signal is supplied to the source electrode 718sB via the source bus line, and a necessary charge is written in the pixel electrode 723 based on a gate signal from the gate bus lines.

As illustrated, a transparent electrically-conductive layer 721 may be provided as a common electrode on the flattening film 720, and the third insulating layer 722 may be provided between the transparent electrically-conductive layer (common electrode) 721 and the pixel electrode 723. In this case, the pixel electrode 723 may have an opening in the form of a slit. Such an active matrix substrate 700 is applicable to, for example, FFS (Fringe Field Switching) mode display devices. The FFS mode is a transverse electric field mode in which a pair of electrodes are provided on one substrate such that an electric field can be applied to liquid crystal molecules in a direction parallel to the substrate surface (transverse direction). In this example, an electric field produced is represented by a line of electric force extending from the pixel electrode 723 and passing through the liquid crystal layer (not shown) and then through the slit opening of the pixel electrode 723 before reaching the common electrode 721. This electric field includes a component transverse to the liquid crystal layer. As a result, a transverse electric field can be applied across the liquid crystal layer. In the transverse electric field mode, the liquid crystal molecules do not rise from the substrate, and therefore, there is an advantage that a wide viewing angle can be realized as compared with the vertical electric field mode.

As the second thin film transistor 710B of the present embodiment, the TFT 10 that has previously been described with reference to FIG. 2 to FIG. 6 can be used. When the TFT 10 of FIG. 2 to FIG. 6 is applied, the gate electrode 2, the gate insulating layer 3, the oxide semiconductor layer 4, the source electrode 5 and the drain electrode 6 of the TFT 10 may respectively correspond to the gate electrode 715B, the second insulating layer (gate insulating layer) 716, the oxide semiconductor layer 717, the source electrode 718sB and the drain electrode 718dB shown in FIG. 17.

As a TFT which is a constituent of the check circuit 770 shown in FIG. 16 (check TFT), the thin film transistor 710B that is an oxide semiconductor TFT may be used.

Although not shown, the check TFT and the check circuit may be provided in, for example, a region to which the driver IC 750 shown in FIG. 16 is to be mounted. In this case, the check TFT is provided between the driver IC 750 and the substrate 711.

In the illustrated example, the first thin film transistor 710A has a top gate configuration where the crystalline silicon semiconductor layer 713 is provided between the gate electrode 715A and the substrate 711 (underlayer film 712). On the other hand, the second thin film transistor 710B has a bottom gate configuration where the gate electrode 715B is provided between the oxide semiconductor layer 717 and the substrate 711 (underlayer film 712). By using such a configuration, increase in the number of manufacturing steps and the manufacturing cost can be effectively suppressed in integrally forming two different types of thin film transistors 710A, 710B on the same substrate 711.

The TFT configuration of the first thin film transistor 710A is not limited to the above-described examples. For example, the first thin film transistor 710A may have a bottom gate configuration.

The second insulating layer 716, which is the gate insulating film of the second thin film transistor 710B, may be extended to a region in which the first thin film transistor 710A is to be formed and may function as an interlayer insulating film which covers the gate electrode 715A and the crystalline silicon semiconductor layer 713 of the first thin film transistor 710A. In the case where the interlayer insulating film of the first thin film transistor 710A and the gate insulating film of the second thin film transistor 710B are thus provided in the same layer (second insulating layer) 716, the second insulating layer 716 may have a multilayer structure. For example, the second insulating layer 716 may have a multilayer structure including a hydrogen donating layer which is capable of supplying hydrogen (e.g., silicon nitride layer) and an oxygen donating layer provided on the hydrogen donating layer which is capable of supplying oxygen (e.g., silicon oxide layer).

The gate electrode 715A of the first thin film transistor 710A and the gate electrode 715B of the second thin film transistor 710B may be provided in the same layer. The source and drain electrodes 718sA, 718dA of the first thin film transistor 710A and the source and drain electrodes 718sB, 718dB of the second thin film transistor 710B may be provided in the same layer. Being “provided in the same layer” refers to being formed using the same film (electrically-conductive film). With such a configuration, increase in the number of manufacturing steps and the manufacturing cost can be suppressed.

(Display Device)

An active matrix substrate (semiconductor device) of an embodiment of the present invention is suitably used for a display device. The display device includes an active matrix substrate of an embodiment of the present invention, a counter substrate arranged so as to oppose the active matrix substrate, and a display medium layer provided between the active matrix substrate and the counter substrate. In the foregoing, an active matrix substrate of a liquid crystal display device which performs displaying in a transverse electric field mode, such as FFS mode, has been described as an example. However, the present invention is also applicable to an active matrix substrate of a liquid crystal display device which performs displaying in a vertical electric field mode where the voltage is applied in the thickness direction of the liquid crystal layer (for example, TN mode and vertical alignment mode). An active matrix substrate of an embodiment of the present invention is also suitably used for display devices which are different from liquid crystal display devices (display devices which have a display medium layer different from the liquid crystal layer). For example, an active matrix substrate of an embodiment of the present invention is also used for electrophoretic display devices, organic EL (Electroluminescence) display devices, etc.

In the liquid crystal display device of Patent Document No. 2, a highly-absorbent flattening resin film is covered with a dampproof protecting film, whereby entry of moisture into the flattening resin film is suppressed. On the other hand, in a liquid crystal display device which includes an active matrix substrate 100 of an embodiment of the present invention, entry of moisture can be sufficiently prevented by the protecting layer 20. Therefore, it is not necessary to form a dampproof protecting film on the organic insulating layer 7. Even when a dampproof protecting film is provided on the organic insulating layer 7 and the edge face of the organic insulating layer 7 is provided under the sealant, stable TFT characteristics can be realized. This is because, even if a crack is formed in the protecting film on the organic insulating layer 7 by the spacer inside the sealant and moisture enters the organic insulating layer 7, entry of moisture into the TFT 10 can be prevented by the protecting layer 20.

### INDUSTRIAL APPLICABILITY

According to an embodiment of the present invention, in a semiconductor device which includes oxide semiconductor TFTs, stable TFT characteristics can be realized. A semiconductor device of an embodiment of the present invention is suitably used as an active matrix substrate for, for example, a display device.

### REFERENCE SIGNS LIST

1 substrate
2 gate electrode
2s lateral surface of gate electrode
3 gate insulating layer
3a silicon nitride layer
3b silicon oxide layer
4 oxide semiconductor layer
4c channel region
4s source region
4d drain region
4e1, 4e2 edge of oxide semiconductor layer
5 source electrode
5a lower layer of source electrode
5b upper layer of source electrode
6 drain electrode
6a lower layer of drain electrode
6b upper layer of drain electrode
7 organic insulating layer
7o opening
8 dielectric layer
8o opening
10 thin film transistor (TFT)
10′ circuit TFT
20 protecting layer
20a silicon oxide layer
20b silicon nitride layer
30 pixel electrode
30a slit
32 common electrode
100, 700 semiconductor device (active matrix substrate)
CH contact hole
DL channel length direction
DW channel width direction
G scan line (gate bus line)
S signal line (source bus line)
P pixel
DR display region
FR peripheral region (frame region)
TP tapered portion of gate electrode

1. A semiconductor device comprising:
a substrate;
a plurality of thin film transistors supported by the substrate; and
a protecting layer covering the plurality of thin film transistors,
wherein each of the plurality of thin film transistors is a back channel etch type thin film transistor, the back channel etch type thin film transistor including a gate electrode provided on the substrate, a gate insulating layer covering the gate electrode, an oxide semiconductor layer which is provided on the gate insulating layer and which opposes the gate electrode with the gate insulating layer interposed therebetween, and a source electrode and a drain electrode which are electrically coupled with the oxide semiconductor layer,
the gate electrode includes a tapered portion defined by a lateral surface which has a tapered shape, and
when viewed in a direction normal to a substrate surface, a periphery of the oxide semiconductor layer includes an edge which extends in a direction intersecting a channel width direction and which is more internal than an edge of the gate electrode in the channel width direction, a distance from the edge of the oxide semiconductor layer to an inside end of the tapered portion is not less than 1.5 μm.

2. The semiconductor device of claim 1, wherein the protecting layer is an inorganic insulating layer which is made of an inorganic insulative material.

3. The semiconductor device of claim 1, wherein the protecting layer includes a silicon oxide layer which is in contact with the oxide semiconductor layer and a silicon nitride or silicon nitride oxide layer provided on the silicon oxide layer.

4. The semiconductor device of claim 1, wherein the semiconductor device is an active matrix substrate which has a display region defined by a plurality of pixels and a peripheral region located around the display region.

5. The semiconductor device of claim 4, wherein
the semiconductor device includes a pixel thin film transistor provided in each of the plurality of pixels, and
the plurality of thin film transistors include the pixel thin film transistor.

6. The semiconductor device of claim 4, wherein
the semiconductor device includes a peripheral circuit which is provided in the peripheral region and which includes at least one circuit thin film transistor, and
the plurality of thin film transistors include the at least one circuit thin film transistor.

7. The semiconductor device of claim 1, wherein the oxide semiconductor layer includes an In—Ga—Zn—O based semiconductor.

8. The semiconductor device of claim 7, wherein the In—Ga—Zn—O based semiconductor includes a crystalline portion.

9. The semiconductor device of claim 1, wherein the oxide semiconductor layer has a multilayer structure.

10. A display device comprising:
an active matrix substrate;
a counter substrate located opposite to the active matrix substrate; and
a display medium layer provided between the active matrix substrate and the counter substrate,
wherein the active matrix substrate is the semiconductor device as set forth in claim 1.
